(19) United States
(12) Patent Application Publication
(10) Pub. No.: US 2026/0027489 A1
(43) Pub. Date: Jan. 29, 2026

(54) SELF-CONTAINED MOBILE PERFORMANCE STRUCTURES

(71) Applicants: Jon Greeney, Portland, OR (US); Yoko Greeney, Portland, OR (US)

(72) Inventors: Jon Greeney, Portland, OR (US); Yoko Greeney, Portland, OR (US)

(21) Appl. No.: 18/782,512

(22) Filed: Jul. 24, 2024

(51) Int. Cl. A63J 1/00; A63J 5/02; B60P 3/025; B60S 9/02; H03F 3/183; H04R 1/02; H04R 3/00

(52) U.S. Cl. CPC A63J 1/00; A63J 5/02; B60P 3/0252; B60S 9/02; H04R 1/025; H04R 3/00; H03F 3/183; H03F 2200/03; H04R 2499/13

(57) ABSTRACT

Mobile performance structures including a trailer, an enclosure, an energy storage system, an audio system, and a photovoltaic system. The enclosure is mounted to the trailer. The energy storage system is supported on the trailer. The audio system is installed in the enclosure and powered by the energy storage system. The photovoltaic system is mounted to the enclosure and electrically coupled to the energy storage system. In some examples, the mobile performance structures include a deck, an actuator, an electronic display, and/or a lighting system.

### BACKGROUND

The present disclosure relates generally to structures facilitating live or recorded performances. In particular, self-contained mobile performance structures are described.

Auditoriums, concert halls, theaters, and amphitheaters are culturally important structures because they facilitate live and recorded performances for audiences. While these conventional performance structures are effective to facilitate performances, they are limited to facilitating performances at fixed locations. There are many instances where a structure facilitating performances at various locations would be beneficial.

For example, attending a performance at a fixed location may not be convenient or feasible for some people if they reside far away from the fixed location. However, those people may be able to attend a performance that takes place closer to where they reside. It would be advantageous to have a performance structure that could be readily transported to different locations to facilitate performances for people who would not otherwise be able to experience them.

Conventional performance structures often conduct performances indoors in confined spaces, which may not be safe from a public health standpoint. In the event of a pandemic or when rates of infectious disease transmission are high, it is typically desirable or necessary for people to maintain distance from each other in outdoor settings. It would be desirable to facilitate outdoor performances in settings where relatively small numbers of people may attend the performance with ample space between them.

Certain performances may be more conducive to smaller venues or outdoor venues. For example, a performance may be intended for less than 100 people and such a performance would be awkward and financially infeasible in a concert venue with a capacity of 20,000 people. It would be beneficial to have a performance structure that could travel to a smaller venue when smaller numbers of people are expected to attend.

A handful of mobile performance structures are known to exist, but they are not entirely satisfactory. Conventional mobile performance structures often lack power wiring and thus lack sound amplification, lighting, and video display capabilities. As a result, such unwired performance structures are limited in the types of performances they can facilitate. To accommodate amplified or illuminated performances, unwired structures require external power cables, which are often unsightly and inconvenient.

Certain mobile performance structures have some degree of power wiring incorporated within them, but require connecting to external power supplies. Such mobile performance structures are thus limited to performance locations where access to an external power supply is available.

Thus, there exists a need for mobile performance structures that improve upon and advance the design of known performance structures. Examples of new and useful mobile performance structures relevant to the needs existing in the field are discussed below.

### SUMMARY

The present disclosure is directed to mobile performance structures including a trailer, an enclosure, an energy storage system, an audio system, and a photovoltaic system. The enclosure is mounted to the trailer. The energy storage system is supported on the trailer. The audio system is installed in the enclosure and powered by the energy storage system. The photovoltaic system is mounted to the enclosure and electrically coupled to the energy storage system. In some examples, the mobile performance structures include a deck, an actuator, an electronic display, and/or a lighting system.

In some examples, the enclosure includes a base, a roof, and sidewalls. The roof may be spaced from the base. The sidewalls extend from the base to the roof around a portion of a periphery of the enclosure.

This document describes certain examples where the enclosure includes a stage mounted to the base. The stage may be configured to support performers during a performance. The sidewalls partially surround the stage.

In select embodiments, the sidewalls define a stage opening to reveal the stage to performance attendees located outside the enclosure.

As described below, in particular instances the enclosure includes a door mounted to the sidewalls at the stage opening. The door may be configured to selectively move between an open configuration and a closed configuration. The stage may be revealed when the door is in the open configuration. The stage may be covered by the door when the door is in the closed configuration.

In some examples, the door is pivotally mounted to the sidewalls proximate the top of the enclosure. The door may function as an awning when pivoted to the open configuration.

This document describes certain examples where the deck moveably mounts to the trailer proximate the base of the enclosure. The deck may be configured to move between an extended configuration and a retracted configuration. The deck may be disposed beyond the enclosure in the extended configuration. The deck may be disposed underneath the enclosure in the retracted configuration.

In select embodiments, the deck is moveably mounted to the trailer proximate the stage opening. The deck may be disposed in front of the stage when the deck is in the extended configuration. The deck may be configured to support performers during a performance when the deck is in the extended configuration.

As described below, in particular instances the deck is disposed underneath the door functioning as an awning and protected from rain by the door when the door is in the open configuration and the deck is in the extended configuration.

In some examples, the actuator is mounted to the enclosure. The actuator may be configured to move the deck between the extended configuration and the retracted configuration.

This document describes certain examples where the actuator is powered by the energy storage system.

In select embodiments, the enclosure defines a deck recess underneath the stage. The deck recess may be configured to receive the deck in the retracted configuration.

As described below, in particular instances the deck includes a deck platform and deck legs. The deck legs couple to the deck platform. The deck legs are configured to selectively extend to the ground when the deck is in the extended configuration to support the deck platform from the ground.

In some examples, the speaker recess is defined in the sidewalls proximate the stage opening. The audio system may include a speaker mounted within the speaker recess. The speaker may be mounted within the speaker recess facing away from the enclosure to project sound to performance attendees.

This document describes certain examples where the audio system includes an amplifier mounted to the enclosure in a position not visible outside the enclosure. The amplifier may drive the speaker.

In select embodiments, the display recess is defined in one of the sidewalls proximate the stage opening. The electronic display may mount in the display recess and face away from the enclosure to be visible to performance attendees. The electronic display may be powered by the energy storage system.

As described below, in particular instances the lighting system is configured to illuminate the stage. The lighting system may be powered by the energy storage system.

In some examples, the energy storage system includes a rechargeable battery.

This document describes certain examples where the trailer includes a trailer platform, wheels, and trailer legs. The trailer platform may support the enclosure. The wheels support the trailer platform from the ground. The trailer legs mount to the trailer platform. The trailer legs are configured to selectively extend to the ground to support the trailer platform from the ground in a level orientation.

In some examples, the trailer legs are electrically powered by the energy storage device.

### BRIEF DESCRIPTION OF THE DRAWINGS

FIG. 1 is a perspective view of a first embodiment of a mobile performance structure in a transport configuration coupled to a vehicle.

FIG. 2 is a perspective view of the mobile performance structure shown in FIG. 1 in a performance configuration with a performer supported on a deck extended in front of an enclosure, performers supported on a stage inside the enclosure, and trailer legs extended to the ground to maintain the enclosure in a level orientation.

FIG. 3 is a front elevation view of the mobile performance structure shown in FIG. 1.

FIG. 4 is a side elevation view of the mobile performance structure shown in FIG. 1 with a door in an open configuration a deck in an extended configuration.

FIG. 5 is a top elevation view of the mobile performance structure shown in FIG. 1 with the door in the open configuration the deck in the extended configuration and depicting solar panels mounted on a roof.

FIG. 6 is a front elevation view of the deck and an actuator configured to selectively extend and retract the deck.

FIG. 7 is a view inside the enclosure depicting an energy storage system, a lighting system, and components of an audio system.

### DETAILED DESCRIPTION

The disclosed mobile performance structures will become better understood through review of the following detailed description in conjunction with the figures. The detailed description and figures provide merely examples of the various inventions described herein. Those skilled in the art will understand that the disclosed examples may be varied, modified, and altered without departing from the scope of the inventions described herein. Many variations are contemplated for different applications and design considerations; however, for the sake of brevity, each and every contemplated variation is not individually described in the following detailed description.

Throughout the following detailed description, examples of various mobile performance structures are provided. Related features in the examples may be identical, similar, or dissimilar in different examples. For the sake of brevity, related features will not be redundantly explained in each example. Instead, the use of related feature names will cue the reader that the feature with a related feature name may be similar to the related feature in an example explained previously. Features specific to a given example will be described in that particular example. The reader should understand that a given feature need not be the same or similar to the specific portrayal of a related feature in any given figure or example.

### Definitions

The following definitions apply herein, unless otherwise indicated.

“Substantially” means to be more-or-less conforming to the particular dimension, range, shape, concept, or other aspect modified by the term, such that a feature or component need not conform exactly. For example, a “substantially cylindrical” object means that the object resembles a cylinder, but may have one or more deviations from a true cylinder.

“Comprising,” “including,” and “having” (and conjugations thereof) are used interchangeably to mean including but not necessarily limited to, and are open-ended terms not intended to exclude additional elements or method steps not expressly recited.

Terms such as “first”, “second”, and “third” are used to distinguish or identify various members of a group, or the like, and are not intended to denote a serial, chronological, or numerical limitation.

“Coupled” means connected, either permanently or releasably, whether directly or indirectly through intervening components.

“Communicatively coupled” means that an electronic device exchanges information with another electronic device, either wirelessly or with a wire-based connector, whether directly or indirectly through a communication network.

“Controllably coupled” means that an electronic device controls operation of another electronic device.

### Self-Contained Mobile Performance Structures

With reference to the figures, self-contained mobile performance structures will now be described. The mobile performance structure discussed herein function to facilitate live and recorded performances at various locations.

The reader will appreciate from the figures and description below that the presently disclosed mobile performance structures address many of the shortcomings of conventional performance structures. For example, the novel mobile performance structures beneficially facilitate performances at various locations rather than being fixed to one location. As a result, performances may be readily conducted in locations closer to where different groups of people reside, which makes attending a performance more feasible and convenient. Thus, the novel mobile performance structures enable more people to attend performances than would otherwise be possible.

The novel mobile performance structures desirably facilitate outdoor performances in settings where relatively small numbers of people may attend the performance with ample space between them. Rather than being limited to performances indoors in confined spaces, which may not be safe from a public health standpoint, the novel mobile performance structures facilitate conducting performances in a manner safer for public health. In the event of a pandemic or when rates of infectious disease transmission are high, the novel mobile performance structures allow people to maintain distance from each other in outdoor settings while enjoying a performance.

Beneficially, the novel mobile performance structures can travel to a smaller venue when a smaller number of people are expected to attend a performance. As a result, the novel mobile performance structures facilitate performances that are more conducive to smaller venues or outdoor venues than fixed, large venues that would make smaller performances awkward and financially infeasible.

Advantageously, the novel mobile performance structures include power wiring to support sound amplification, lighting, and video display capabilities. As a result, the novel performance structures can facilitate a wide range of performances. Further, the novel performance structures do not require external power cables, which makes the mobile structures aesthetically pleasing, organized, and convenient.

Another benefit of the novel mobile performance structures described herein is that they include onboard energy storage systems. Accordingly, the novel mobile performance structures do not require connecting to an external power supply when powering sound systems, stage lighting, and video displays during a performance. Thus, the novel mobile performance structures are not limited by proximity to external power supply connections and can facilitate performances in remote locations.

### Contextual Details

Ancillary features relevant to the mobile performance structures described herein will first be described to provide context and to aid the discussion of the mobile performance structures.

### Vehicle

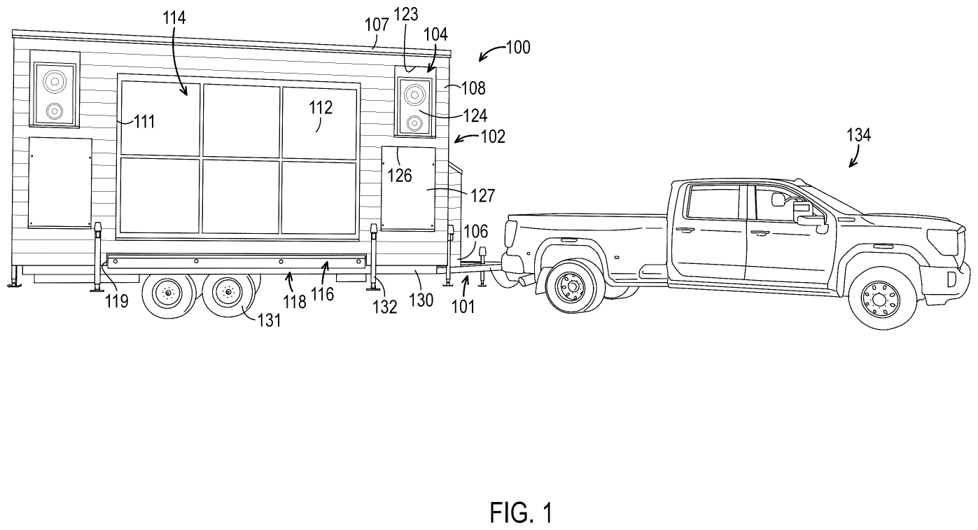

The mobile performance structures described herein may be transported to different locations when pulled by a vehicle. One suitable vehicle in the form of a pickup truck, vehicle 134, is shown in FIG. 1 coupled to a trailer 101 of mobile performance structure 100. However, the mobile performance structure may be towed by a wide variety of vehicles, including pickup trucks, semi-trucks, sport utility vehicles, and the like.

### Mobile Performance Structure Embodiment One

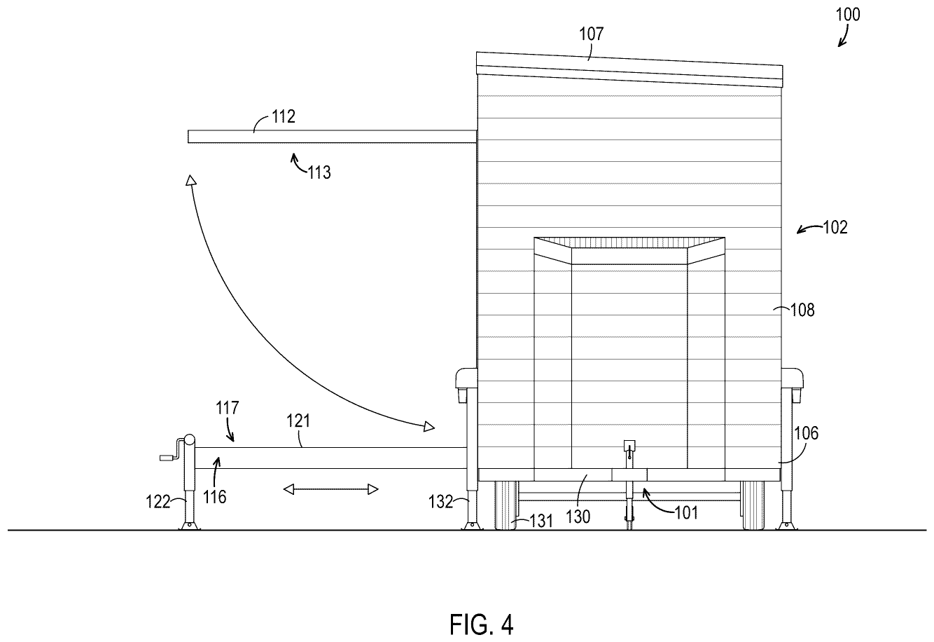

With reference to FIGS. 1-7, a mobile performance structure 100 will now be described as a first example of a mobile performance structure. Mobile performance structure 100 functions to support performances at different locations. As described further below, mobile performance structure supports performances enhanced with audio, video, and lighting components.

As shown in FIGS. 1-7, mobile performance structure 100 includes a trailer 101, an enclosure 102, an energy storage system 103, an audio system 104, a photovoltaic system 105, a deck 116, an actuator 120, electronic displays 127, and a lighting system 128. The components of mobile performance structure 100 are discussed below.

The size and shape of the mobile performance structure may be varied as needed for a given application. In some examples, the mobile performance structure is larger or smaller relative to the other components than depicted in the figures.

### Trailer

Trailer 101 serves to support enclosure 102 and the other components of mobile performance structure 100. As shown in FIG. 1, trailer 101 enables enclosure 102 and the other components to be moved to different locations when pulled by vehicle 134.

The reader can see in FIGS. 1-4 that trailer 101 includes a trailer platform 130, wheels 131, and trailer legs 132. The components of trailer 101 are discussed in detail below.

The size and shape of the trailer may be varied as needed for a given application. Different sized enclosures may warrant different sized trailers. In some examples, the trailer is larger or smaller relative to the other components than depicted in the figures.

The trailer may be any currently known or later developed type of trailer. Various trailer types exist and could be used in place of the trailer shown in the figures. In addition to the types of trailers existing currently, it is contemplated that the mobile performance structures described herein could incorporate new types of trailers developed in the future.

### Trailer Platform

As depicted in FIGS. 1-4, trailer platform 130 supports enclosure 102. As shown in FIG. 1, trailer platform 130 may be selectively coupled to vehicle 134 to tow mobile performance structure 100 to different locations.

As shown in FIGS. 1-3, wheels 131 mount to trailer platform 130. Trailer legs 132 secure to trailer platform 130 and to enclosure 102.

In the present example, the trailer platform is composed of metal. However, the trailer platform may be composed of any currently known or later developed material suitable for trailer applications. Suitable materials include metals, polymers, ceramics, wood, and composite materials.

The size and shape of the trailer platform may be varied as needed for a given application. In some examples, the trailer platform is larger or smaller relative to the other components than depicted in the figures.

### Wheels

Wheels 131 facilitate moving mobile performance structure 100 to different locations. With reference to FIGS. 1-3, wheels 131 support trailer platform 130 from the ground.

The size of the wheels may be varied as needed for a given application. In some examples, the wheels are larger or smaller relative to the other components than depicted in the figures.

The number of wheels in the mobile performance structure may be selected to meet the needs of a given application. The reader should appreciate that the number of wheels may be different in other examples than is shown in the figures. For instance, some mobile performance structure examples include additional or fewer wheels than described in the present example.

The wheels may be any currently known or later developed type of wheel. Various wheel types exist and could be used in place of the wheels shown in the figures. In addition to the types of wheels existing currently, it is contemplated that the mobile performance structures described herein could incorporate new types of wheels developed in the future.

### Trailer Legs

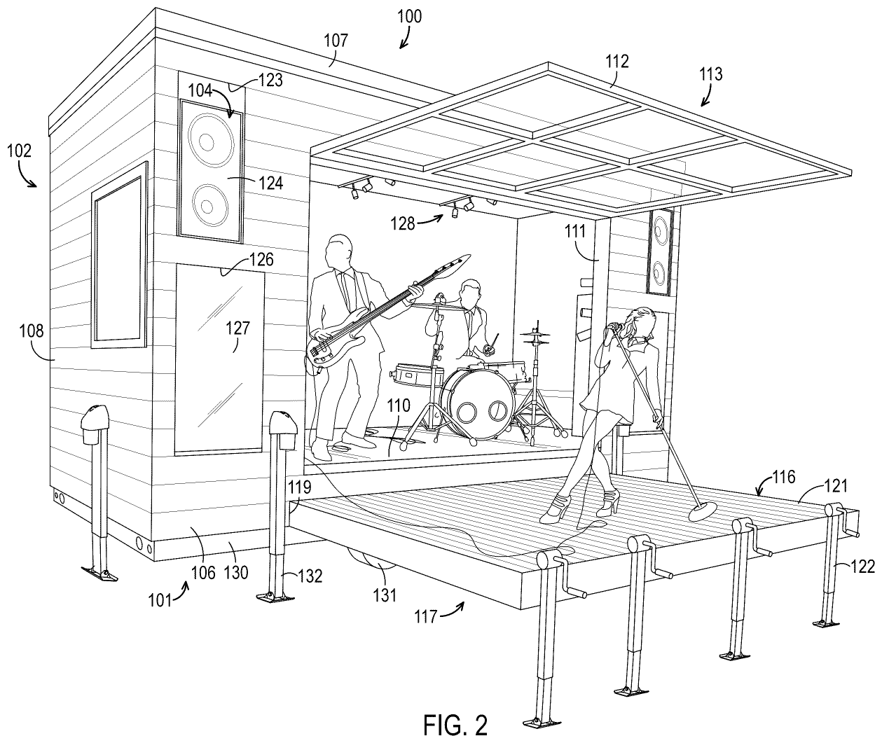

The role of trailer legs 132 is to selectively stabilize trailer 101 and mobile performance structure 100. The reader can see in FIGS. 1-4 that trailer legs 132 mount to trailer platform 130 and enclosure 102 at selected positions around trailer platform 130 and enclosure 102. As shown in FIGS. 2-4, trailer legs 132 are configured to selectively extend to the ground to support trailer platform 130 from the ground in a level orientation.

In the present example, trailer legs 132 are electrically powered by energy storage device 103. In other examples, the trailer legs are configured to be manually raised and lowered. In some examples, the trailer legs are pneumatically actuated.

The number of trailer legs in the mobile performance structure may be selected to meet the needs of a given application. The reader should appreciate that the number of trailer legs may be different in other examples than is shown in the figures. For instance, some mobile performance structure examples include additional or fewer trailer legs than described in the present example.

The size and shape of the trailer legs may be varied as needed for a given application. In some examples, the trailer legs are larger or smaller relative to the other components than depicted in the figures.

In the present example, the trailer legs are composed of metal. However, the trailer legs may be composed of any currently known or later developed material suitable for support applications. Suitable materials include metals, polymers, ceramics, wood, and composite materials.

The trailer legs may be any currently known or later developed type of support. Various support types exist and could be used in place of the trailer legs shown in the figures. In addition to the types of supports existing currently, it is contemplated that the mobile performance structures described herein could incorporate new types of supports developed in the future.

### Enclosure

Enclosure 102 functions to enclose and protect components of mobile performance structure 100, including energy storage system 103, audio system 104, and lighting system 128. Further, enclosure 102 serves to externally support components of mobile performance structure 100, such as photovoltaic system 105, deck 116, actuator 120, and electronic displays 127.

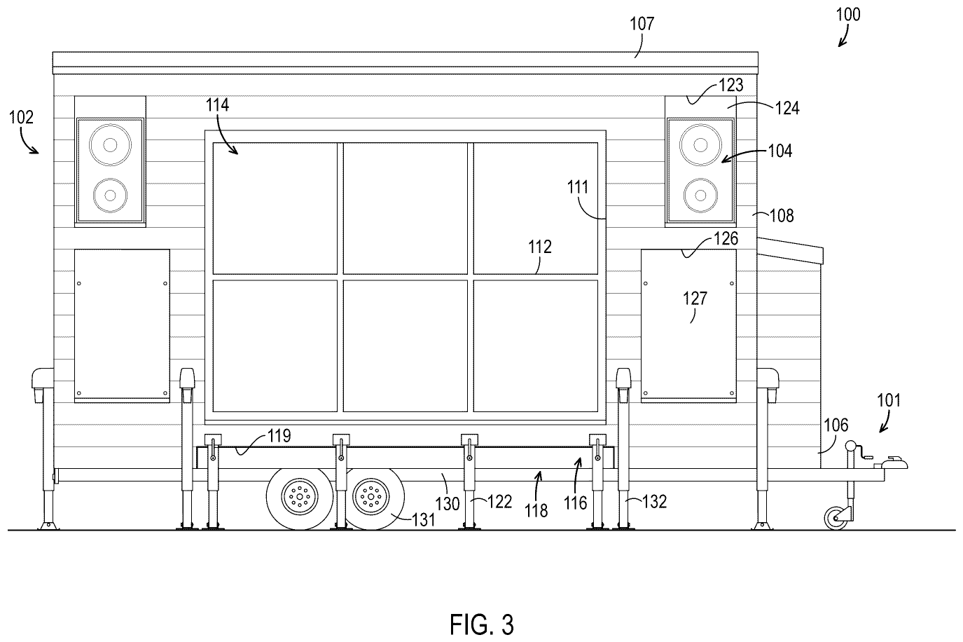

With reference to FIGS. 1-4, enclosure 102 is mounted to trailer 101. As shown in FIGS. 1-4 and 7, enclosure 102 includes a base 106, a roof 107, sidewalls 108, a door 112, and a stage 110. With reference to FIGS. 2 and 3, enclosure 102 defines deck recess 119 underneath stage 110. The components of enclosure 102 are discussed in more detail below.

The size and shape of the enclosure may be varied as needed for a given application. In some examples, the enclosure is larger or smaller relative to the other components than depicted in the figures.

In the present example, the enclosure is composed of wood. However, the enclosure may be composed of any currently known or later developed material suitable for enclosure or dwelling applications. Suitable materials include metals, polymers, ceramics, wood, and composite materials.

### Base

Base 106 functions to support enclosure 102 and other components of mobile performance structure 100 from below. Further, base 106 serves to couple to trailer platform 130.

The base may be any currently known or later developed type of floor structure. Various floor types exist and could be used in place of the base shown in the figures. In addition to the types of floors existing currently, it is contemplated that the mobile performance structures described herein could incorporate new types of floors developed in the future.

The size and shape of the base may be varied as needed for a given application. In some examples, the base is larger or smaller relative to the other components than depicted in the figures.

In the present example, the base is composed of wood. However, the base may be composed of any currently known or later developed material suitable for base or floor applications. Suitable materials include metals, polymers, ceramics, wood, and composite materials.

### Roof

The role of roof 107 is to protect components of mobile performance structure 100 from the elements. Further, roof 107 functions to support photovoltaic system 105. As shown in FIGS. 1-4 and 7, roof 107 is spaced from base 106.

In the present example, the roof is composed of wood and covered with roof pans. However, the roof may be composed of any currently known or later developed material suitable for roof applications. Suitable materials include metals, polymers, ceramics, wood, and composite materials.

The roof may be any currently known or later developed type of roof. Various roof types exist and could be used in place of the roof shown in the figures. In addition to the types of roofs existing currently, it is contemplated that the mobile performance structures described herein could incorporate new types of roofs developed in the future.

The size and shape of the roof may be varied as needed for a given application. In some examples, the roof is larger or smaller relative to the other components than depicted in the figures.

### Sidewalls

Sidewalls 108 functions to laterally enclose enclosure 102 and to support roof 107. The reader can see in FIGS. 1-4 and 7 that sidewalls 108 extend from base 106 to roof 107 around a portion of a periphery of enclosure 102. As depicted in FIGS. 1-4 and 7, sidewalls 108 partially surround stage 110.

With reference to FIGS. 1-3 and 7, sidewalls 108 define a stage opening 111. Stage opening 111 reveals stage 110 to performance attendees located outside enclosure 102. The size and shape of the stage opening may be varied as needed for a given application. In some examples, the stage opening is larger or smaller than depicted in the figures.

The number of stage openings in the mobile performance structure may be selected to meet the needs of a given application. The reader should appreciate that the number of stage openings may be different in other examples than is shown in the figures. For instance, some mobile performance structure examples include additional stage openings than described in the present example.

The reader can see in FIGS. 1-3 that speaker recesses 123 are defined in sidewalls 108 proximate stage opening 111. However, the speaker recesses may be defined in other locations of the sidewalls. Speaker recesses 123 receive speakers 124 of audio system 104. The size and shape of the speaker recesses may be varied as needed for a given speaker design. In some examples, the speaker recesses are larger or smaller relative to the other components than depicted in the figures.

Display recesses 126 are defined in a front sidewall 108 proximate stage opening 111 and below speaker recesses 123. However, the display recesses may be defined in other locations of the sidewalls. Display recesses 126 function to receive electronic displays 127. In some examples, the electronic displays mount to the sidewalls without a recess formed in the sidewall for them.

The size and shape of the display recesses may be varied as needed for a given electronic display design. In some examples, the display recesses are larger or smaller relative to the other components than depicted in the figures.

The number of speaker and display recesses in the mobile performance structure may be selected to meet the needs of a given application. The reader should appreciate that the number of recesses may be different in other examples than is shown in the figures. For instance, some mobile performance structure examples include additional or fewer recesses than described in the present example.

The size and shape of the sidewalls may be varied as needed for a given application. In some examples, the sidewalls are larger or smaller relative to the other components than depicted in the figures.

In the present example, the sidewalls are composed of wood. However, the sidewalls may be composed of any currently known or later developed material suitable for wall applications. Suitable materials include metals, polymers, ceramics, wood, and composite materials.

### Stage

As shown in FIG. 2, stage 110 is configured to support performers during a performance. The reader can see in FIGS. 1-4 that stage 110 is mounted to base 106.

As depicted in FIG. 1, stage 110 is covered by door 112 when door 112 is in closed configuration 114. The reader can see in FIGS. 1-3 and 7 that stage 110 is revealed when door 112 is in open configuration 113.

The size and shape of the stage may be varied as needed for a given application. In some examples, the stage is larger or smaller relative to the other components than depicted in the figures.

The stage may be any currently known or later developed type of stage. Various stage types exist and could be used in place of the stage shown in the figures. In addition to the types of stages existing currently, it is contemplated that the mobile performance structures described herein could incorporate new types of stages developed in the future.

### Door

Door 112 serves to provide selective access into enclosure 102. Further, door 112 selectively reveals and blocks the view of stage 110 through stage opening 111. Moreover, door 112 selectively functions as an awning to provide protection from the sun, rain, and snow underneath door 112.

As depicted in FIGS. 1-5 and 7, door 112 is mounted to sidewalls 108 at stage opening 111. In particular, as shown in FIGS. 1-5 and 7, door 112 is pivotally mounted to sidewalls 108 proximate the top of enclosure 102.

With reference to FIGS. 1-5 and 7, door 112 is configured to selectively move between an open configuration 113 and a closed configuration 114. The reader can see in FIGS. 2-5 and 7 that door 112 functions as an awning when pivoted to open configuration 113. Deck 116 underneath door 112 in open configuration 113 is protected from the sun, rain, and snow.

The number of doors in the mobile performance structure may be selected to meet the needs of a given application. The reader should appreciate that the number of doors may be different in other examples than is shown in the figures. For instance, some mobile performance structure examples include additional or fewer doors than described in the present example.

The door may be any currently known or later developed type of door. Various door types exist and could be used in place of the door shown in the figures. In addition to the types of doors existing currently, it is contemplated that the mobile performance structures described herein could incorporate new types of doors developed in the future.

The size and shape of the door may be varied as needed for a given application. In some examples, the door is larger or smaller relative to the other components than depicted in the figures.

In the present example, the door is composed of wood. However, the door may be composed of any currently known or later developed material suitable for door applications. Suitable materials include metals, polymers, ceramics, wood, and composite materials.

### Deck Recess

The role of deck recess 119 is to selectively receive deck 116. As depicted in FIGS. 2 and 3, deck recess 119 is configured to receive deck 116 when deck 116 is in retracted configuration 118. The reader can see in the figures that deck recess 119 is disposed underneath stage 110.

In the present example, the size and shape of deck recess 119 is complementarily configured with the size and shape of deck 116. The size and shape of the deck recess may be varied as needed for a given application. In some examples, the deck recess is larger or smaller relative to the other components than depicted in the figures.

### Energy Storage System

Energy storage system 103 serves to store electricity generated by photovoltaic system 105. Further, energy storage system 103 functions to supply power to audio system 104, actuator 120, electronic displays 127, and lighting system 128.

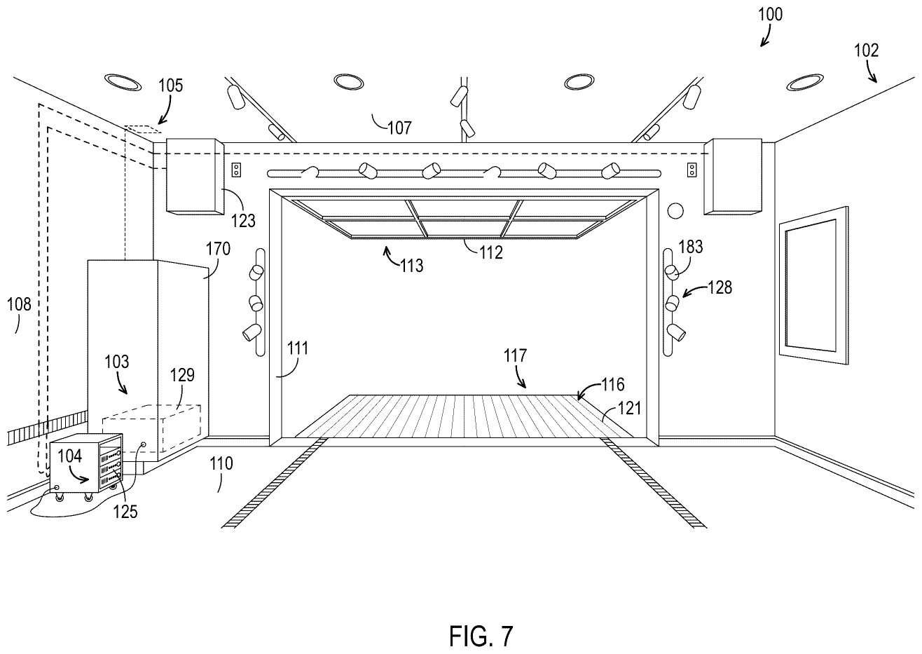

With reference to FIG. 7, energy storage system 103 is supported on trailer 101 in enclosure 102. Energy storage system 103 is electrically coupled to photovoltaic system 105, audio system 104, actuator 120, electronic displays 127, and lighting system 128. Energy storage system 103 may also electrically couple to a power outlet to receive power from a power grid.

As schematically shown in FIG. 7, energy storage system 103 includes a rechargeable battery 129 within a cabinet 170. In the present example, energy storage system 103 includes additional rechargeable batteries (not pictured) within cabinet 170.

The rechargeable battery may be any currently known or later developed type of rechargeable battery, including lithium based batteries. Various battery types exist and could be used in place of the rechargeable battery shown in the figures. In addition to the types of batteries existing currently, it is contemplated that the mobile performance structures described herein could incorporate new types of batteries developed in the future.

The size and shape of the rechargeable battery may be varied as needed for a given application. In some examples, the rechargeable battery is larger or smaller relative to the other components than depicted in the figures.

The number of rechargeable batteries in the mobile performance structure may be selected to meet the needs of a given application. The reader should appreciate that the number of rechargeable batteries may be different in other examples than is shown in the figures. For instance, some mobile performance structure examples include additional or fewer rechargeable batteries than described in the present example.

### Audio System

The role of audio system 104 is to support performances from mobile performance structure 100 by projecting amplified sound to performance attendees. The reader can see in FIG. 7 that audio system 104 is installed in enclosure 102 and powered by energy storage system 103.

In the present example, audio system 104 includes speakers 124, integrated amplifiers 125, and associated cables. The audio system may include any currently known or later developed additional or alternative components, such as audio processors, media players, and the like.

The number of audio systems in the mobile performance structure may be selected to meet the needs of a given application. The reader should appreciate that the number of audio systems may be different in other examples than is shown in the figures. For instance, some mobile performance structure examples include additional or fewer audio systems than described in the present example.

The audio system may be any currently known or later developed type of audio system. Various audio system types exist and could be used in place of the audio system shown in the figures. In addition to the types of audio systems existing currently, it is contemplated that the mobile performance structures described herein could incorporate new types of audio systems developed in the future.

### Speaker

Speakers 124 serve to project sound when driven by amplifier 125. As depicted in FIGS. 1-3, speakers 124 are mounted within speaker recesses 123 defined in enclosure 102. In particular, as shown in FIGS. 1-3, speaker 124 is mounted within speaker recess 123 facing away from enclosure 102. Speakers 124 facing away from enclosure 102 serves to project sound towards performance attendees.

The speaker may be any currently known or later developed type of audio speaker. Various audio speaker types exist and could be used in place of the speaker shown in the figures. In addition to the types of audio speakers existing currently, it is contemplated that the mobile performance structures described herein could incorporate new types of audio speakers developed in the future.

The size and shape of the speaker may be varied as needed for a given application. In some examples, the speaker is larger or smaller relative to the other components than depicted in the figures.

The number of speakers in the mobile performance structure may be selected to meet the needs of a given application. The reader should appreciate that the number of speakers may be different in other examples than is shown in the figures. For instance, some mobile performance structure examples include additional or fewer speakers than described in the present example.

### Amplifier

Amplifier 125 provides the power necessary to amplify sound signals and to drive speakers 124. With reference to FIG. 7, amplifier 125 is mounted to enclosure 102 in a position not visible outside enclosure 102.

The amplifier may be any currently known or later developed type of audio amplifier. Various audio amplifier types exist and could be used in place of the amplifier shown in the figures. In addition to the types of audio amplifiers existing currently, it is contemplated that the mobile performance structures described herein could incorporate new types of audio amplifiers developed in the future.

### Photovoltaic System

Photovoltaic system 105 serves to convert solar radiation into electricity. The electricity generated by photovoltaic system 105 is stored in energy storage system 103 and utilized by components of mobile performance structure 100, such as audio system 104, actuator 120, electronic displays 127, and lighting system 128.

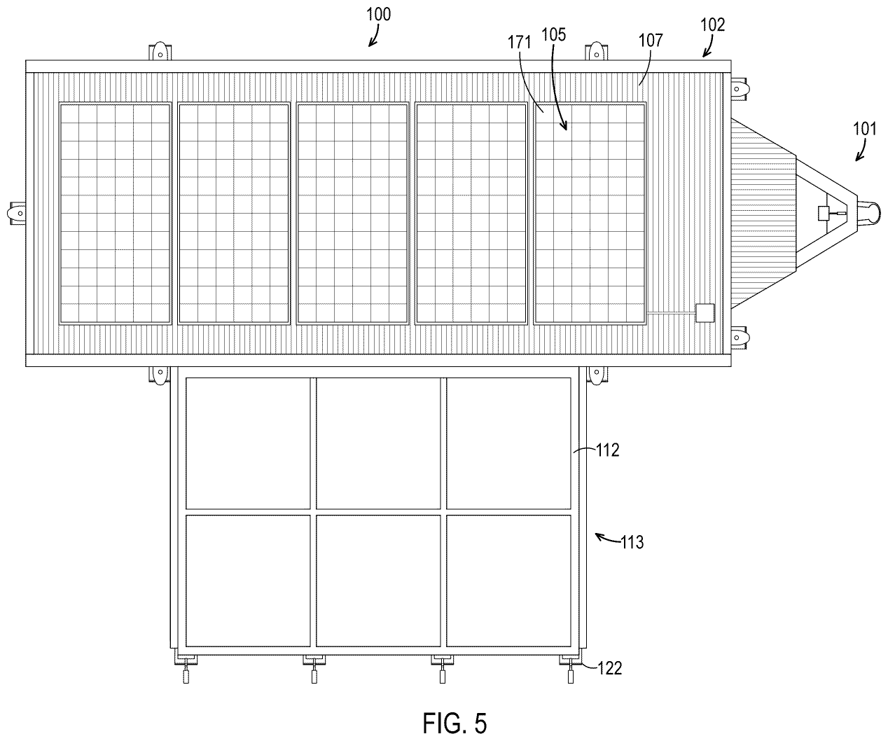

With reference to FIGS. 5 and 7, photovoltaic system 105 is mounted to enclosure 102. In particular, photovoltaic system 105 is mounted on roof 107 of enclosure 102. Photovoltaic system 105 mounting to roof 107 positions it well to be irradiated by the sun.

As schematically shown in FIG. 7, photovoltaic system 105 is electrically coupled to energy storage system 103 with power cables. Accordingly, electricity generated by photovoltaic system 105 may be stored in energy storage system 103 and later utilized by components of mobile performance structure 100.

The number of photovoltaic systems in the mobile performance structure may be selected to meet the needs of a given application. The reader should appreciate that the number of photovoltaic systems may be different in other examples than is shown in the figures. For instance, some mobile performance structure examples include additional or fewer photovoltaic systems than described in the present example.

In the present example, photovoltaic system 105 includes multiple solar panels 171. However, the photovoltaic system may be any currently known or later developed type of photovoltaic system. Various photovoltaic system types exist and could be used in place of the photovoltaic system shown in the figures. In addition to the types of photovoltaic systems existing currently, it is contemplated that the mobile performance structures described herein could incorporate new types of photovoltaic systems developed in the future.

### Deck

Deck 116 functions as a retractable stage extension. Deck 116 is retracted when transporting mobile performance structure 100, and deck 116 may be selectively extended when mobile performance structure 100 is used for a performance at a given location.

With reference to FIGS. 1-7, deck 116 moveably mounts to trailer 101 proximate base 106 of enclosure 102. Deck 116 is selectively moved relative to enclosure 102 by actuator 120. In some examples, the deck is additionally or alternatively moved relative to the enclosure manually.

As depicted in FIGS. 1-7, deck 116 is configured to move between an extended configuration 117 and a retracted configuration 118. As shown in FIG. 1, deck 116 is disposed underneath enclosure 102 in retracted configuration 118. The reader can see in FIGS. 2, 4, 5, and 7 that deck 116 is disposed beyond enclosure 102 in extended configuration 117. More particularly, as shown in FIGS. 2, 4, 5, and 7, deck 116 is disposed in front of stage 110 when deck 116 is in extended configuration 117.

With reference to FIGS. 2-5 and 7, deck 116 is disposed underneath door 112. When door 112 is in open configuration 113 functioning as an awning 115 and deck 116 is in extended configuration 117, deck 116 is protected from sun, rain, and snow by door 112 disposed above it.

As shown in FIGS. 2-4, deck 116 includes a deck platform 121 and deck legs 122. The components of deck 116 are discussed further below.

The size and shape of the deck may be varied as needed for a given application. In some examples, the deck is larger or smaller relative to the other components than depicted in the figures.

In the present example, the deck is composed of wood. However, the deck may be composed of any currently known or later developed material suitable for deck applications. Suitable materials include metals, polymers, ceramics, wood, and composite materials.

### Deck Platform

Deck platform 121 functions as a stage extension when deck 116 is in extended configuration 117. As shown in FIG. 2, deck platform 121 supports performers sitting or standing on it.

The size and shape of the deck platform may be varied as needed for a given application. In some examples, the deck platform is larger or smaller relative to the other components than depicted in the figures.

In the present example, the deck platform is composed of wood. However, the deck platform may be composed of any currently known or later developed material suitable for platform applications. Suitable materials include metals, polymers, ceramics, wood, and composite materials.

### Deck Legs

Deck legs 122 serve to support deck platform 121 from the ground. As depicted in FIGS. 2-4, deck legs 122 are configured to selectively extend to the ground when deck 116 is in extended configuration 117 to support deck platform 121 from the ground. In the example shown in FIGS. 2-4, deck legs 122 removably couple to deck platform 121.

In the present example, deck legs 122 are manually extended and retracted to support and level deck platform 121 from the ground. In other examples, the deck legs are electrically or pneumatically actuated to change their length.

In the example shown in the figures, deck legs 122 are selectively positioned underneath and coupled to deck platform 121 when deck 116 is in extended configuration 117. When deck 116 is in retracted configuration 118, deck legs 122 are decoupled from deck platform 121 and stored for later use. In some examples, however, the deck legs remain coupled to the deck platform when the deck is in the retracted configuration.

The deck legs may be any currently known or later developed type of support. Various support types exist and could be used in place of the deck legs shown in the figures. In addition to the types of supports existing currently, it is contemplated that the mobile performance structures described herein could incorporate new types of supports developed in the future.

The size and shape of the deck legs may be varied as needed for a given application. In some examples, the deck legs is larger or smaller relative to the other components than depicted in the figures.

### Actuator

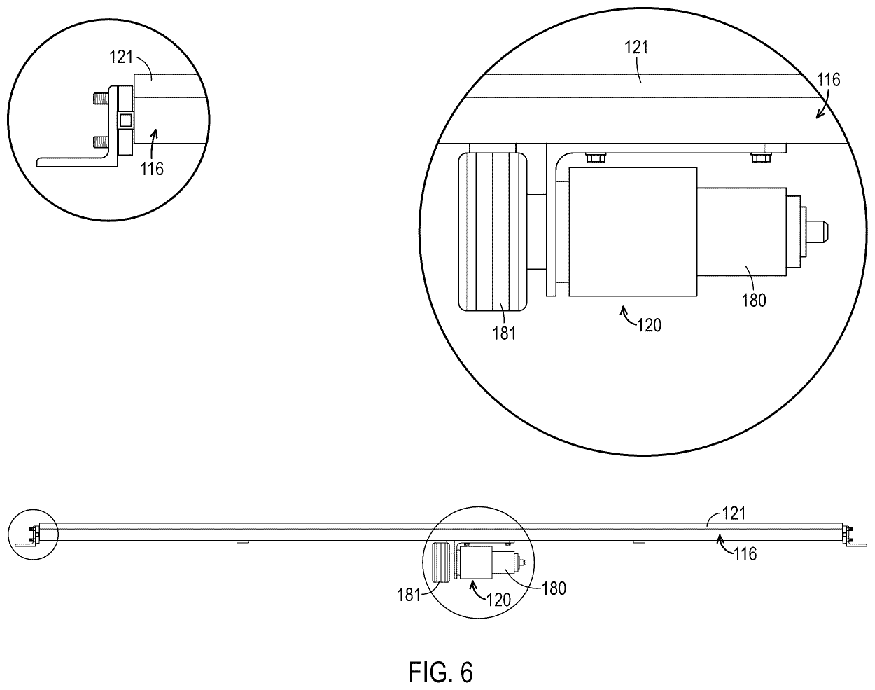

Actuator 120 functions to selectively move deck 116. In particular, as shown in FIG. 6, actuator 120 is configured to move deck 116 between extended configuration 117 and retracted configuration 118.

Actuator 120 is mounted to enclosure 102 proximate deck recess 119. When activated, actuator 120 either drives deck 116 out of deck recess 119 into extended configuration 117 or retracts deck 116 within deck recess 119 in retracted configuration 118.

In the present example, actuator 120 is powered by energy storage system 103. In some examples, the actuator is manually operated.

As shown in FIG. 6, actuator 120 includes a motor 180 and a drive wheel 181. However, the actuator may be any currently known or later developed type of actuator. Various actuator types exist and could be used in place of the actuator shown in the figures. In addition to the types of actuators existing currently, it is contemplated that the mobile performance structures described herein could incorporate new types of actuators developed in the future.

### Electronic Display

The role of electronic displays 127 is to display text and/or video content to performance attendees. In the example shown in the figures, electronic display 127 is powered by energy storage system 103.

As depicted in FIGS. 1-3, electronic displays 127 mount in display recesses 126. As shown in FIGS. 1-3, electronic displays 127 face way from enclosure 102. Electronic displays 127 facing away from enclosure 102 makes the media content they display visible to performance attendees outside enclosure 102.

The number of electronic displays in the mobile performance structure may be selected to meet the needs of a given application. The reader should appreciate that the number of electronic displays may be different in other examples than is shown in the figures. For instance, some mobile performance structure examples include additional or fewer electronic displays than described in the present example.

The size and shape of the electronic display may be varied as needed for a given application. In some examples, the electronic display is larger or smaller relative to the other components than depicted in the figures.

The electronic display may be any currently known or later developed type of electronic display. Various electronic display types exist and could be used in place of the electronic display shown in the figures. In addition to the types of electronic displays existing currently, it is contemplated that the mobile performance structures described herein could incorporate new types of electronic displays developed in the future.

### Lighting System

The reader can see in FIG. 7 that lighting system 128 is configured to illuminate stage 110. The lighting system may additionally or alternatively illuminate deck 116 when deck 116 is extended from enclosure 102.

As depicted in FIG. 7, lighting system 128 includes a plurality of illumination devices 183. Lighting system 128 is electrically coupled to and powered by energy storage system 103.

The lighting system may be any currently known or later developed type of lighting system. Various lighting system types exist and could be used in place of the lighting system shown in the figures. In addition to the types of lighting systems existing currently, it is contemplated that the mobile performance structures described herein could incorporate new types of lighting systems developed in the future.

The number of lighting systems in the mobile performance structure may be selected to meet the needs of a given application. The reader should appreciate that the number of lighting systems may be different in other examples than is shown in the figures. For instance, some mobile performance structure examples include additional or fewer lighting systems than described in the present example.

The disclosure above encompasses multiple distinct inventions with independent utility. While each of these inventions has been disclosed in a particular form, the specific embodiments disclosed and illustrated above are not to be considered in a limiting sense as numerous variations are possible. The subject matter of the inventions includes all novel and non-obvious combinations and subcombinations of the various elements, features, functions and/or properties disclosed above and inherent to those skilled in the art pertaining to such inventions. Where the disclosure or subsequently filed claims recite “a” element, “a first” element, or any such equivalent term, the disclosure or claims should be understood to incorporate one or more such elements, neither requiring nor excluding two or more such elements.

Applicant(s) reserves the right to submit claims directed to combinations and subcombinations of the disclosed inventions that are believed to be novel and non-obvious. Inventions embodied in other combinations and subcombinations of features, functions, elements and/or properties may be claimed through amendment of those claims or presentation of new claims in the present application or in a related application. Such amended or new claims, whether they are directed to the same invention or a different invention and whether they are different, broader, narrower or equal in scope to the original claims, are to be considered within the subject matter of the inventions described herein.

1. A mobile performance structure, comprising:
a trailer;
an enclosure mounted to the trailer;
an energy storage system operatively supported on the trailer;
an audio system installed in the enclosure and powered by the energy storage system; and
a photovoltaic system mounted to the enclosure and electrically coupled to the energy storage system.

2. The mobile performance structure of claim 1, wherein the enclosure includes:
a base;
a roof spaced from the base; and
sidewalls extending from the base to the roof around a portion of a periphery of the enclosure.

3. The mobile performance structure of claim 2, wherein:
the enclosure includes a stage mounted to the base;
the stage is configured to support performers during a performance; and
the sidewalls partially surrounding the stage.

4. The mobile performance structure of claim 3, wherein the sidewalls define a stage opening to reveal the stage to performance attendees located outside the enclosure.

5. The mobile performance structure of claim 4, wherein:
the enclosure includes a door mounted to the sidewalls at the stage opening; and
the door is configured to selectively move between an open configuration and a closed configuration;
the stage is revealed when the door is in the open configuration; and
the stage is covered by the door when the door is in the closed configuration.

6. The mobile performance structure of claim 5, wherein:
the door is pivotally mounted to the sidewalls proximate the top of the enclosure; and
the door functions as an awning when pivoted to the open configuration.

7. The mobile performance structure of claim 6, wherein:
the mobile performance structure further comprises a deck moveably mounted to the trailer proximate the base of the enclosure;
the deck is configured to move between an extended configuration and a retracted configuration;
the deck is disposed beyond the enclosure in the extended configuration; and
the deck is disposed underneath the enclosure in the retracted configuration.

8. The mobile performance structure of claim 7, wherein:
the deck is moveably mounted to the trailer proximate the stage opening;
the deck is disposed in front of the stage when the deck is in the extended configuration; and
the deck is configured to support performers during a performance when the deck is in the extended configuration.

9. The mobile performance structure of claim 8, wherein the deck is disposed underneath the door functioning as an awning and protected from rain by the door when the door is in the open configuration and the deck is in the extended configuration.

10. The mobile performance structure of claim 9, wherein:
the enclosure defines a deck recess underneath the stage; and
the deck recess is configured to receive the deck in the retracted configuration.

11. The mobile performance structure of claim 8, wherein the deck includes:
a deck platform; and
deck legs coupled to the deck platform and configured to selectively extend to the ground when the deck is in the extended configuration to support the deck platform from the ground.

12. The mobile performance structure of claim 4, wherein:
a speaker recess is defined in the sidewalls proximate the stage opening;
the audio system includes a speaker mounted within the speaker recess; and
the speaker is mounted within the speaker recess facing away from the enclosure to project sound to performance attendees.

13. The mobile performance structure of claim 12, wherein:
the audio system includes an amplifier mounted to the enclosure in a position not visible outside the enclosure; and
the amplifier drives the speaker.

14. The mobile performance structure of claim 3, wherein:
the mobile performance structure further comprises a lighting system configured to illuminate the stage; and
the lighting system is powered by the energy storage system.

15. The mobile performance structure of claim 4, wherein:
a display recess is defined in one of the sidewalls proximate the stage opening;
the mobile performance structure further comprises an electronic display mounted in the display recess and facing way from the enclosure to be visible to performance attendees; and
the electronic display is powered by the energy storage system.

16. The mobile performance structure of claim 1, wherein the energy storage system includes a rechargeable battery.

17. The mobile performance structure of claim 1, wherein the trailer includes:
a trailer platform supporting the enclosure;
wheels supporting the trailer platform from the ground; and
trailer legs mounted to the trailer platform and configured to selectively extend to the ground to support the trailer platform from the ground in a level orientation.

18. The mobile performance structure of claim 17, wherein the trailer legs are electrically powered by the energy storage device.
